(19) United States
(12) Patent Application Publication
(10) Pub. No.: US 2024/0012075 A1
(43) Pub. Date: Jan. 11, 2024

(54) Lower Parasitic Multi-Turn MRI Phased Array Coil

(71) Applicants: Haoqin Zhu, Winnipeg (CA); Gong Zhang, Winnipeg (CA)

(72) Inventors: Haoqin Zhu, Winnipeg (CA); Gong Zhang, Winnipeg (CA)

(21) Appl. No.: 18/320,643

(22) Filed: May 19, 2023

Related U.S. Application Data
(60) Provisional application No. 63/344,181, filed on May 20, 2022.

(51) Int. Cl. G01R 33/34

(52) U.S. Cl. CPC G01R 33/34084

(57) ABSTRACT

Described herein is a lower parasitic multi-turn MRI phased array coil wherein the geometry is substantially identical between the coil turns. The potential of every corresponding point between the turns of the coil is also substantially equal, for example by using capacitors of substantially equal value and/or using substantially equal lengths of copper trace between breaks. As a result of this arrangement, the potential between coil turns is substantially equal, for example, with substantially equal capacitor value and substantially equal break point on conductor trace. This in turn reduces parasitics between turns because the geometry of each turn of the coil is substantially identical. The lower parasitic multi-turn MRI phased array coil is suitable for use with wired or wireless phased array coils, and is particularly well suited for use with lower field MRI systems.

### PRIOR APPLICATION INFORMATION

The instant application claims the benefit of U.S. Provisional Patent Application 63/344,181, filed May 20, 2022 and entitled “LOWER PARASITIC MULTI-TURN MRI PHASED ARRAY COIL”, the entire contents of which are incorporated herein by reference for all purposes.

### BACKGROUND OF THE INVENTION

As used herein, “AC” in reference to voltage or current refers to voltage or current that changes whereas “DC” in reference to voltage or current refers to voltage or current that is steady or constant.

According to Faraday's law, the electromotive force (emf) can be calculated by:

$$ε = - N \frac{d φ}{dt}$$

This equation can also be used for MRI signal strength calculation when:
N: the number of turns of a multi turn coil
φ: the magnetic flux through a single loop.

According to this equation, in theory, multi-turn MRI coil designs can increase the Signal-to-Noise ratio (SNR) when compared to single loop coils over a range of coil diameters.

However, in practice, the parasitic capacitance between turns in the coil increases coil loss. As will be apparent to those of skill in the art, “parasitic capacitance” refers to an unwanted capacitance that exists between the parts of an electronic component or circuit simply because of their proximity to each other. As a consequence, multi-turn loop coil performance is worse than single loop coil due to this parasitic effect.

The most common parasitic resistances are series resistance and shunt resistance, which reduce the sensitivity (or Q factor) of multi-turn MRI coil by dissipating RF signal power in the parasitic resistances.

The equivalent model used to describe an inductor in terms of its parasitic capacitance is a parallel RLC circuit with lumped elements and is shown in FIG. 1.

As known to those of skill in the art, all inductors have three parasitics that influence AC behavior in a real system:
1) Equivalent series resistance (ESR): This arises due to the contact resistance on the input leads.
2) Equivalent parallel capacitance (EPC): Winding capacitance, which is the primary source of parasitic capacitance.
3) Equivalent parallel resistance (EPR): Coil resistance due to the finite conductivity of the inductor coil.

In an actual coil, the impact of these losses is quantified by the Q factor (the quality factor). Q is loosely related to bandwidth in general but the strict relationship is based on the response of a series or parallel connection of a resistor (R), an inductor (L), and a capacitor (C).

Coil Q factor: Q=ωL/R
R—Coil resistance R=R_{coil}+Rₛₐₘₚₗₑ+Rₑₓₜᵣₐ
L—“coil inductance”

The equivalent resistance is the sum of the resistance due to conductor losses R_{coil}, resistance given by RF current losses, sample loss Rₛₐₘₚₗₑ, and resistances found in attached capacitors, for example, due to soldering, radiated losses and parasitic loss, Rₑₓₜᵣₐ.

MRI coil signal to noise ratio can be calculated as ∝\sqrt{Q}, wherein the more parasitic loss there is, the lower SNR will be. As discussed above, multi-turn coils are particularly impacted by this.

There is a misconception in the art that the Q factor is not important, based on the assumption that the preamplifier decoupling kills the coil Q factor, which is incorrect. Rather, poor quality electrical components (such as bad capacitors, inductor, pin diode), bad soldering, high resistance conductor, and coil wire interference lower a coil's Q factor and therefore lower SNR

For a Standard 1.5 T or 3.0 T phased array MRI coil, an unload Q factor value of around 100 to 150 is considered “good”.

For example, the prior art teaches a multi-turn coil wherein “each conductive layer is rotated about a central-axis to minimise the conductor overlap” “to minimize resistance from both the skin and proximity effects at high frequency” while including several break capacitors symmetrically placed. However, the inventor believes that in this arrangement, the peracetic capacitance and resistance is reduced. The disadvantages of this method are as follows:
(1) the complexity of coil structure results in a massive coil trace area; and
(2) difficulty applying these coils to a multi-channel phased array coil.

### SUMMARY OF THE INVENTION

According to a first aspect of the invention, there is provided a multi-turn magnetic resonance imaging (MRI) radiofrequency (RF) coil comprising two or more turns, wherein the RF coil has an overall geometry such that each respective turn is substantially mirrored by an adjacent turn, such that the geometry is substantially identical between the coil turns.

In some embodiments, each one specific point along a turn of the coil has a substantially corresponding point at an identical geometric position of the adjacent turn.

In some embodiments, potential at each one specific point along a turn is substantially identical to potential at each corresponding specific point on the adjacent turn.

In some embodiments, the substantially identical potential between adjacent points is achieved by using capacitors of substantially equal value and/or using substantially equal lengths of copper trace between breaks.

### BRIEF DESCRIPTION OF THE DRAWINGS

FIG. 1 shows the equivalent model schematically. PRIOR ART.

FIG. 2 is a schematic diagram of one embodiment of the multi-turn MRI coil of the invention.

FIG. 3 is a phasor diagram of two turn MRI coil circuit.

FIG. 4 is a graph showing the coil element Q factor measured at 1.0 Tesla.

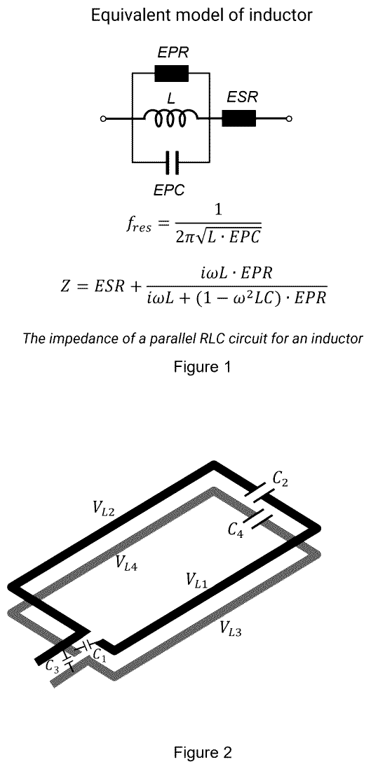

### DESCRIPTION OF THE PREFERRED EMBODIMENTS

Unless defined otherwise, all technical and scientific terms used herein have the same meaning as commonly understood by one of ordinary skill in the art to which the invention belongs. Although any methods and materials similar or equivalent to those described herein can be used in the practice or testing of the present invention, the preferred methods and materials are now described. All publications mentioned hereunder are incorporated herein by reference.

With reference to the drawings, FIG. 2 shows one embodiment of the invention.

As can be seen, the multi-turn coil has an overall geometry such that each respective turn is substantially mirrored by an adjacent turn, such that the geometry is substantially identical between the coil turns. Specifically, each one specific point along a turn of the coil has a substantially corresponding point at an identical geometric position.

Furthermore, the potential of every corresponding point between the turns of the coil is substantially equal, for example, by using capacitors of substantially equal value and/or using substantially equal lengths of copper trace between breaks, or any other suitable means known in the art for maintaining substantially equal potential between corresponding points.

As a result of this arrangement, the potential between coil turns is substantially equal, for example, with substantially equal capacitor value and substantially equal break point on conductor trace. This in turn reduces parasitics between turns because the geometry of each turn of the coil is substantially identical.

That is, in some embodiments, the multi-turn coil of the invention comprises two or more coil segments, each respective one coil segment having a specific geometric shape that is substantially identical to each respective other coil segment or geometrically corresponding coil segment, that is, so that each respective one coil segment mirrors each respective other coil segment such that the geometry is substantially identical between a respective one coil turn of a first coil segment and a corresponding respective one coil turn of a second coil segment. Furthermore, potential at each one specific point along a respective one coil turn of a first coil segment is substantially identical to potential at a corresponding one specific point along a corresponding respective one coil turn of a second coil segment. As discussed herein, the substantially identical potential between adjacent points is achieved by using capacitors of substantially equal value and/or using substantially equal lengths of copper trace between breaks.

For example, with reference to FIG. 2, L2 would be considered part of one coil segment and L4 would be considered the corresponding part to L2 of the second coil segment. Furthermore, L1 and L2 would be considered one coil segment while L3 and L4 would be considered a second coil segment. Furthermore, FIG. 2 demonstrates how the adjacent turns of the multi-turn coil mirror each other such that there is substantially identical geometry therebetween.

As used in this context, substantially refers to the acceptable tolerance of variations in shape, capacitance and copper length. For improving the coil Q factor, 5% tolerance capacitor and a few mm copper length tolerance is “substantially” equal.

In some embodiments, the multi-turn coil has an overall geometry such that each respective turn is mirrored by an adjacent turn, such that the geometry is identical between the coil turns. Specifically, each one specific point along a turn of the coil has a corresponding point at an identical or corresponding geometric position in the overall multi-turn coil.

Furthermore, the potential of every corresponding point between the turns of the coil is equal, for example, by using capacitors of equal value and/or using equal lengths of copper trace between breaks, or any other suitable means known in the art for maintaining equal potential between corresponding points.

As a result of this arrangement, the potential between coil turns is equal, for example, with equal capacitor value and equal break point on conductor trace. This in turn reduces parasitics between turns because the geometry of each turn of the coil is identical.

Furthermore, as a result of this arrangement, the coil trace area is the same as for a normal phased array coil, meaning that the multi-turn coil of the invention can be used without any modifications or special equipment.

In one embodiment, the coil is built with double side flex Kapton PCB. The Core dielectric thickness is 3.0 to 8.0 mils (0.07-0.2 mm), but is not limited to the flex PCB. The coil copper trace can be rigid/flex copper wire. However, any suitable material known in the art for the construction of MRI coils may be used and are within the scope of the invention.

As will be appreciated by one of skill in the art, there is no specific requirement for spacing between turns of the multi-turn MRI coil. Specifically, while in general it is true that in theory, the larger the spacing between turns, the less parasitics are an issue; however, the multi-turn coil of the invention overcomes typical spacing limitations.

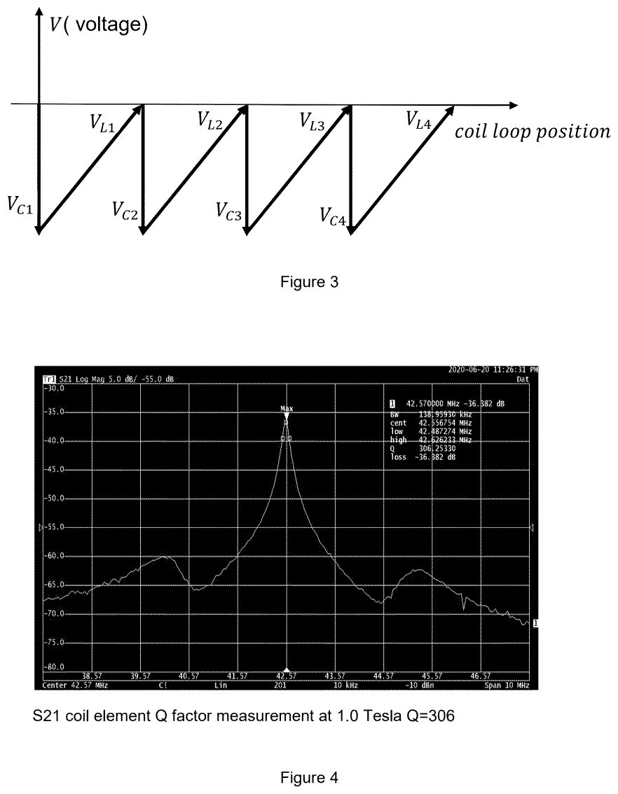

The invention is further illustrated in FIG. 3 which shows a phasor diagram in which the equipotential wires between turns is accomplished by proper selection of equal capacitor value and equal break wire length between capacitors, specifically, equipotential wires at segment of V_{L2}=V_{L4} and V_{L1}=V_{L3} for every corresponding point. Therefore, the parasitic capacitance between turns is greatly reduced and higher Q is achieved and higher SNR as well.

Furthermore, as can be seen in FIG. 3, the coil Q factor will be increased a lot if all capacitors are equal, and the break point are equal distance. C₁=C₂=C₃=C₄, L₁=L₂=L₃=L₄, V_{C1}=V_{C2}=V_{C3}=VC₄=V_{L1}=V_{L2}=V_{L3}=V_{L4}. Therefore: V_{C1}=V_{C2}=V_{C3}=V_{C4}=V_{L1}=V_{L2}=V_{L3}=V_{L4}.

As will be appreciated by one of skill in the art, the equipotential wires between turns reduces the parasitic current which generate coil loss attributable to the parasitic capacitor, and parasitic resistance. Furthermore, equipotential wires between turns reduce the parasitic current which generate coil loss attributable to the parasitic capacitor and resistance. This in turn increases MRI image SNR.

The end result is a lower parasitic multi-turn MRI phased array coil that has the following properties:
a High Q (>1000) capacitor
Good conductor (lower resistance)
More break capacitors for reducing electric field (E field), therefore reducing the dielectric loss of samples to be imaged.
An added RF balun to eliminate common mode current (noise)
Reduced parasitic capacitance, resistance of coil loop.

For a standard MRI coil as such dormitory coil, the best unload coil Q factor is less than 200. But for the lower parasitics two turn MRI phased array coil of the invention, the Q factor is 306, as shown in FIG. 4.

Thus, the multi-turn MRI phased array coil has a higher Q factor and has increased inductance, while maintaining capacitor value in a reasonable range. For example, the capacitor valve should be much larger than parasitic capacitor value, such as >15 pF.

As will be appreciated by one of skill in the art, dual decoupling circuit at the same break point provides the best decoupling strength.

As a result of this arrangement, the multi-turn coil can be used in a traditional wired MRI phased array coil design but also in wireless phased array coil design. It is even more useful for lower field MRI coil (below 0.5 Tesla) because wired and inductive wireless coil resonate circuit is the same. This is a very important benefit of using this technique, as it can greatly improve MRI phased array coil performance for both wired and wireless. It is even more important for lower field MRI coil (below 0.5 Tesla).

According to RF reciprocity theory (see below), increase B₁ field will boost the sensitivity of phased array coil and also SNR. The definition of B₁ is a magnetic field generated by the unit current which was passed through the coil.

$$ε = - \frac{\partial }{\partial x} ( {\int }_{{V}_{s}} {B}_{1} \cdot MdV )$$

ε: the voltage generated from primary coil
V_{S}: the volume of the sample M
M: the nuclear magnetization
B₁: the RF field generated by the multi-turn receive coil at the position of magnetization if a unite current were passed through it.

The definition of B₁ is a magnetic field generated by the unit current which was passed through the coil. According to the RF reciprocity theory, an increase in B₁ field will boost the sensitivity of the phased array coil and also the SNR. Specifically, the presence of more than one coil will focus the B1 field on the sample; for example, two turns would double the B1 field strength.

While the preferred embodiments of the invention have been described above, it will be recognized and understood that various modifications may be made therein, and the appended claims are intended to cover all such modifications which may fall within the spirit and scope of the invention.

1. A multi-turn magnetic resonance imaging (MRI) radiofrequency (RF) coil comprising two or more turns, wherein the RF coil has an overall geometry such that each respective turn is substantially mirrored by an adjacent turn, such that the geometry is substantially identical between the coil turns.

2. The RF coil according to claim 1 wherein each one specific point along a turn of the coil has a substantially corresponding point at an identical geometric position of the adjacent turn.

3. The RF coil according to claim 2 wherein potential at each one specific point along a turn is substantially identical to potential at each corresponding specific point on the adjacent turn.

4. The RF coil according to claim 3 wherein the substantially identical potential between adjacent points is achieved by using capacitors of substantially equal value and/or using substantially equal lengths of copper trace between breaks.
